(19) United States
(12) Patent Application Publication
(10) Pub. No.: US 2004/0113178 A1
(43) Pub. Date: Jun. 17, 2004

(54) FUSED GATE FIELD EMITTER

(76) Inventor: Colin Wilson, Niskayuna, NY (US)

Correspondence Address: FOLEY AND LARDNER, SUITE 500, 3000 K STREET NW, WASHINGTON, DC, 20007, US

(21) Appl. No.: 10/248,032

(22) Filed: Dec. 12, 2002

(51) Int. Cl. H01L 27/10

(52) U.S. Cl. 257/209

(57) ABSTRACT

There is provided a field emitter device formed on a substrate. The field emitter device includes a voltage supply line, and a plurality of sections of field emitters. Each section includes a conducting gate electrode layer, at least one field emitter tip, and a fuse. The fuse electrically connects the conducting gate electrode layer to the voltage source, and the fuse electrically disconnects the conducting gate electrode layer from the voltage supply line when the voltage and current of the conducting gate electrode layer exceeds a threshold value.

### BACKGROUND OF INVENTION

This invention is related generally to field emitter arrays.

Field emitter arrays (FEAs) generally include an array of field emitter devices. Each emitter device, when properly driven, can emit electrons from the tip of the device. Field emitter arrays have many applications, one of which is in field emitter displays (FEDs), which can be implemented as a flat panel display. In addition to flat panel displays, FEAs have applications as electron sources in microwave tubes, X-ray tubes, and other vacuum microelectronic devices.

FIG. 1 illustrates a portion of a conventional FEA. The field emitter device shown in FIG. 1 is often referred to as a “Spindt-type” FEA. It includes a field emitter tip 12 formed on a semiconductor substrate 10. Refractory metal, carbide, diamond and silicon tips, silicon carbon nanotubes and metallic nanowires are some of the structures known to be used as field emitter tips 12. The field emitter tip 12 is adjacent to an insulating layer 14 and a conducting gate layer 16. By applying an appropriate voltage to the conducting gate layer 16, the current to the field emitter tip 12 passing through semiconductor substrate 10 is controlled.

FIG. 2 illustrates a top view of a conventional FEA including the portion shown in FIG. 1. The conducting gate layer 16 controls current to a number of tips 12 arranged over the substrate 10. The tips 12 are arranged as an array.

FEAs in many prior art designs are susceptible to failure due to gate-to-emitter arcing. A gate overvoltage or an increase in vacuum pressure may produce conditions sufficient for an arc discharge to form between the gate and emitting tip. This happens when an electron avalanche propagates between the two electrodes. Because a single conducting gate layer typically controls current to a large number of field emitter tips, when the short circuit failure occurs all the emitter tips corresponding to a particular gate layer are affected, and failure is catastrophic.

### SUMMARY OF INVENTION

In accordance with one aspect of the present invention, there is provided a field emitter device formed on a substrate. The field emitter device comprises: a voltage supply line; and a plurality of sections of field emitters wherein each section comprises: a conducting gate electrode layer; at least one field emitter tip; and a fuse electrically connecting the conducting gate electrode layer to the voltage supply line, wherein the fuse electrically disconnects the conducting gate electrode layer from the voltage source when the voltage and current of the conducting gate electrode layer exceeds a threshold value.

In accordance with another aspect of the present invention, there is provided a method of forming a field emitter device. The method comprises: forming a voltage supply line; and forming a plurality of sections of field emitters wherein forming each section comprises: forming a conducting gate electrode layer; forming at least one field emitter tip; and forming a fuse electrically connecting the conducting gate electrode layer to the voltage supply line, wherein the fuse electrically disconnects the conducting gate electrode layer from the voltage source when the voltage and current of the conducting gate electrode layer exceeds a threshold value.

### BRIEF DESCRIPTION OF DRAWINGS

FIG. 1 is a side cross sectional view of a prior art field emitter device.

FIG. 2 illustrates a top view of a conventional FEA including the portion shown in FIG. 1.

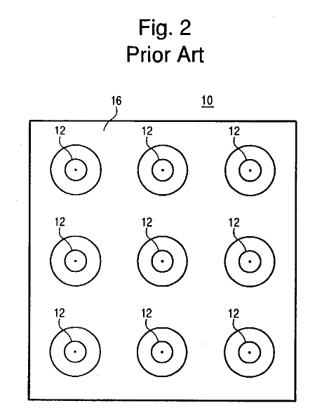

FIG. 3 is a top view of a field emitting device according to a preferred embodiment of the invention.

FIG. 4 is a top view illustrating one particular section of the field emitting device of FIG. 3.

FIG. 5 is a side view along the line A-A of the section illustrated in FIG. 4.

FIG. 6 is a top view of a field emitting device according to another preferred embodiment of the invention.

### DETAILED DESCRIPTION OF THE PREFERRED EMBODIMENTS

The present inventor has realized that segmenting a gate electrode, and its corresponding field emitter tips, into a number of sections, where each section has its own corresponding fuse may overcome the above mentioned problems with gate-emitter arcing. If an arc occurs in one section, that section may be destroyed. The remaining sections, however, are not destroyed because the fuse is set to disconnect the gate electrode when arcing occurs from the remaining sections of the device.

In one embodiment the gate electrode is segmented into sections and a current return wire is provided for each section. The current return wire is thin enough to act as a fuse when its gate electrode begins to conduct too much current. When the gate electrode conducts too much current, the fuse material evaporates or melts and isolates the emitter tip where arcing is occurring along with all the remaining emitter tips that correspond to the gate electrode.

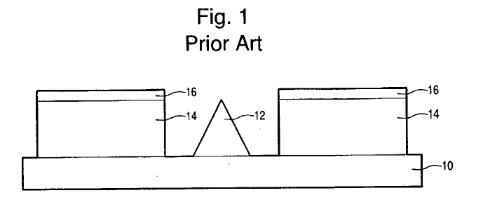

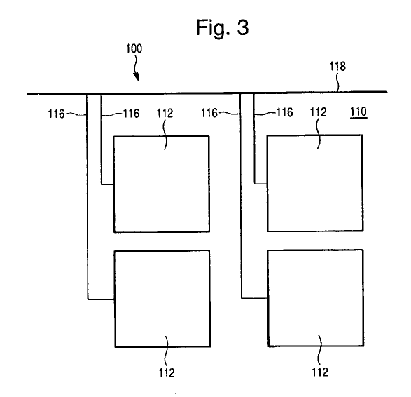

FIGS. 3, 4 and 5 illustrate one preferred embodiment of the invention. FIG. 3 is a top view of this preferred embodiment of illustrating a field emitting device 100 formed on a substrate 110. The device 100 includes a plurality of sections 112 of field emitters. Each of the sections has a corresponding fuse 116 electrically connecting a conducting gate electrode layer (not shown in FIG. 1) to a voltage source such as voltage supply line 118.

The sections 112 may be any shape desired. For example, the sections 112 may be circular, rectangular or triangular. The sections 112 may also be of different size and/or shape.

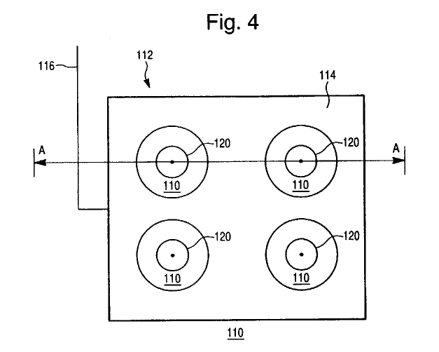

FIG. 4 is a top view showing one particular section 112. The section 112 includes a number of emitter tips 120 arranged as desired. The emitter tips 120 extend up from the substrate 110. The section 112 also includes a conducting gate electrode layer 114. When an appropriate voltage is applied to the conducting gate electrode layer 114, the current to the field emitter tips 120 passing through substrate 110 is controlled as desired. The conducting gate electrode layer 114 controls the current to all of the emitter tips 120 in a particular section 112.

FIG. 4 illustrates four field emitter tips for ease of illustration. In general, the number of field emitter tips will be many more than four, and may be hundreds, thousands, or tens of thousands, for example.

A fuse 116 electrically connects the conducting gate electrode layer 114 to a voltage source such as voltage supply line (not shown in FIG. 4). The fuse 116 is formed of a material and has a cross-section appropriate to allow the fuse material to melt or evaporate at a current corresponding to a threshold voltage of the conducting gate electrode layer 116. The fuse material may be formed of, for example, a metal such as Al, Ni, Mo, Pt or W for example. When the fuse material melts or evaporates the electrical connection is severed between the conducting gate electrode layer 14 and the voltage source, such as voltage supply line 118. The fuse material is designed to melt when the current flowing through it reaches a threshold level, typically of the order of a few micro-amps.

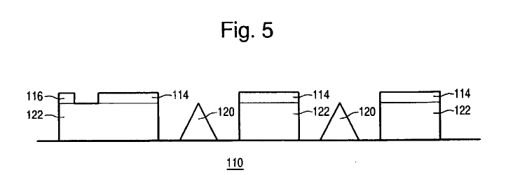

FIG. 5 is a side view along the line A-A of the section 112 illustrated in FIG. 4. In addition to the field emitter tips 120, the conducting gate electrode 114, the fuse 116 and the substrate 110, FIG. 5 illustrates an gate insulating layer 122 disposed between the conducting gate electrode layer 114 and the substrate 110.

The gate insulating layer 122 material may be formed by blanket depositing an insulating material, by any suitable technique, such as CVD or sputtering, followed by patterning the first insulating material. Patterning the first insulating material may be performed using photolithographic techniques, which are well known in the art. Alternatively, the gate insulating layer 122 material may be formed by growing an insulating material directly on the substrate 110, followed by patterning the gate insulating layer 122 material, or by selectively growing the gate insulating layer 122 material on the substrate. The gate insulating layer 122 material may be, for example, silicon dioxide, silicon nitride, or silicon oxynitride.

If the gate insulating layer 122 is formed by growing a material on the substrate, the gate insulating layer 122 may be formed by exposing the substrate 110 to an oxidizing atmosphere. For example, if the substrate 110 is silicon, the gate insulating layer 122 may be formed by exposing the substrate 110 to oxygen gas or water vapor.

The gate insulating layer 122 material may be formed to a thickness of between about 0.5 μm and 5 μm, and more preferably between about 0.5 μm and 1.5 μm. The thickness of the gate insulating layer 122 will depend upon the particular device formed, and it should be thick enough to support an appropriate gate voltage. The thickness of the gate insulating layer 122 may be, for example, about 2.5 μm.

The conducting gate electrode layer 114 may be formed by depositing a conducting material on the gate insulating layer 122. The conducting material may be a metal, such as a refractory metal, for example. The conducting material may be one of molybdenum, niobium, chromium and hafnium, or combinations of these materials, for example. Other conducting materials may be used as are known in the art. The conducting material may be deposited by physical vapor deposition techniques, such as evaporation or sputtering, or by chemical vapor deposition (CVD) techniques. The thickness of the conducting gate electrode layer 114 may be, for example, about 0.4 μm. The thickness of the conducting gate electrode layer 114 will be dependent upon the particular device formed, and should be thick enough to allow conduction of the gate current, as is known in the art.

The conducting gate electrode layer 114 and gate insulating layer 122 may be formed by depositing the gate insulating layer 122 and then the conducting gate electrode layer 114 on the gate insulating layer 122, followed by photolithographically patterning both layers. Alternatively, the gate insulating layer 122 may be patterned first followed by patterning the conducting gate electrode layer 114.

The fuse material of the fuse 116 may be any conductive materials used for fuses in semiconductor devices, for example, molybdenum (Mo), platinum (Pt), tungsten (W), Aluminum (Al), or nickel (Ni). The fuse 116 may be formed by deposition of the fuse material followed by photolithographically patterning the fuse material to form the fuse 116. The fuse 116 and the conducting gate electrode layer 114 may be patterned concurrently, or separately. The thickness and height of the fuse 116 chosen will depend upon the current through the fuse at the particular threshold voltage selected, but should be sized to allow the fuse 116 to melt or evaporate at current levels present at the threshold voltage, such as above several micro-amps.

The voltage supply line 18 of FIG. 3 may be formed by depositing a conducting material over the substrate 110, as is known in the art. The conducting material of the voltage supply line 118 may be a metal, such as aluminum or refractory metal, for example. Other conducting materials may be used as are known in the art. The conducting material may be deposited by physical vapor deposition techniques, such as evaporation or sputtering, or by chemical vapor deposition (CVD) techniques. The voltage supply line 118 may be formed and/or patterned concurrently with the conducting gate electrode layer 114, and may be of the same material.

The field emitter tips 120 may each be formed as a refractory metal tip, a nanotube, a nanowire or other types of emitter tips. If each field emitter tip 120 is formed as a refractory metal tip, each tip 120 may be formed by the so-called “Spindt process”. An example of a Spindt process for depositing a refractory metal tip, for example, is provided in U.S. Pat. No. 5,731,597 to Lee et al, which is incorporated by reference. If the emitter tips 120 comprise a refractory metal, the emitter tips 120 may be formed of molybdenum, niobium, or hafnium, or combinations of these materials, for example.

The field emitter tips 120 may also be formed as nanotubes or nanowires. For example, the emitter tips 120 may be formed as carbon nanotubes or as nanowires. The nanowires may be ZnO, refractory metal, refractory metal carbides, or diamond, for example. Carbon nanotubes may be formed using electric discharge, pulsed laser ablation or chemical vapor deposition, for example. Nanowires can be grown by several known methods, but preferably using electro-deposition.

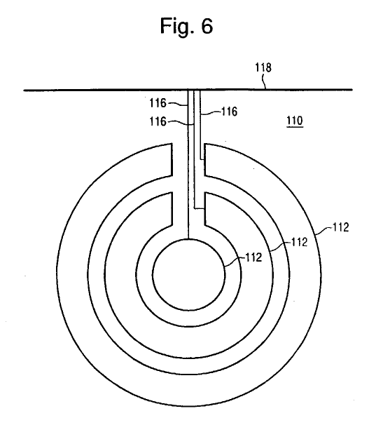

FIG. 6 is a top view according to another preferred embodiment illustrating a field emitting device 100 formed on a substrate 100. In a similar fashion to the embodiment of FIGS. 3-5, in the embodiment of FIG. 6, a field emitting device 100 includes a plurality of sections 112 of field emitters, and each of the sections has a corresponding fuse 116 electrically connecting a conducting gate electrode layer (not shown in FIG. 6) to a voltage source such as voltage supply line 118. However, in the embodiment of FIG. 6, the sections 112 are shaped as a series of concentric rings and a central circular section.

While the invention has been described in detail and with reference to specific embodiments thereof, it will be apparent to one skilled in the art that various changes and modifications can be made therein without departing from the spirit and scope of the invention. Thus, the breadth and scope of the present invention should not be limited by any of the above-described exemplary embodiments, but should be defined only in accordance with the following claims and their equivalents.

1. A field emitter device formed on a substrate comprising:
a voltage supply line; and
a plurality of sections of field emitters wherein each section comprises:
a conducting gate electrode layer;
at least one field emitter tip; and
a fuse electrically connecting the conducting gate electrode layer to the voltage supply line, wherein the fuse electrically disconnects the conducting gate electrode layer from the voltage source when the voltage and current of the conducting gate electrode layer exceeds a threshold value.

2. The field emitter device of claim 1, wherein the threshold value corresponds to a breakdown voltage.

3. The field emitter device of claim 1, wherein the fuse comprises a material selected from Al, Ni, Mo, Pt and W.

4. The field emitter device of claim 1, wherein the plurality of sections include sections shaped as concentric circles.

5. The field emitter device of claim 1, wherein the plurality of sections include sections shaped as rectangles or circles.

6. The field emitter device of claim 1, wherein the plurality of sections include sections of different shapes.

7. The field emitter device of claim 1, wherein the substrate comprises an insulating material.

8. The field emitter device of claim 1, wherein the substrate comprises at least one of silicon, germanium and III-V semiconductor material.

9. The field emitter device of claim 1, wherein the at least one field emitter tip comprises one of a refractory metal tip, a nanotube and a nanowire.

10. The field emitter device of claim 1, wherein the at least one field emitter tip comprises a nanowire comprising one of ZnO, refractory metal, refractory metal carbides, and diamond.

11. The field emitter device of claim 9, wherein the at least one field emitter tip comprises a refractory metal tip comprising one of molybdenum, niobium and hafnium.

12. The field emitter device of claim 1, wherein the at least one field emitter tip comprises a carbon nanotube.

13. A method of forming a field emitter device comprising:
forming a voltage supply line; and
forming a plurality of sections of field emitters wherein forming each section comprises:
forming a conducting gate electrode layer;
forming at least one field emitter tip; and
forming a fuse electrically connecting the conducting gate electrode layer to the voltage supply line, wherein the fuse electrically disconnects the conducting gate electrode layer from the voltage source when the voltage and current of the conducting gate electrode layer exceeds a threshold value.

14. The method of claim 13, wherein the forming each section further comprises:
forming an insulating layer;
depositing a conducting material on the insulating layer;
depositing a fuse material on the insulating layer; and
patterning the conducting material and the fuse material to form the conducting gate electrode layer and the at least one field emitter tip.

15. The method of claim 14, wherein the conducting material and the fuse material are patterned concurrently.
